(19) United States
(12) Patent Application Publication
(10) Pub. No.: US 2010/0001666 A1
(43) Pub. Date: Jan. 7, 2010

(54) MICRO-ELECTRO-MECHANICAL SYSTEM WITH ACTUATORS

(75) Inventors: Mark Thomas Johnson, Eindhoven (NL); Murray Fulton Gillies, Eindhoven (NL); Marc Wilhelmus Gijsbert Deurenberg, Eindhoven (NL); Jacob Marinus Jan Den Toonder, Eindhoven (NL); Roy Van Dijk, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/519,809

(22) PCT Filed: Dec. 17, 2007
(86) PCT No.: PCT/IB07/55144

§ 371 Date: Jun. 18, 2009

(30) Foreign Application Priority Data
Dec. 21, 2006 (EP) 06126885.0

(51) Int. Cl. H01L 41/04

(52) U.S. Cl. 318/116

(57) ABSTRACT

The invention relates to a micro-electro-mechanical system comprising a ciliary actuator (100) having a flexible electrode unit (FE) and a stationary electrode unit (SE), wherein the flexible electrode unit (FE) can be rolled-up or out according to a voltage (V_{PMA}) applied between the flexible and the stationary electrode unit (SE). The invention provides means that allow to bring the actuator into a stable intermediate state (INT) between the totally rolled-up (UP) and the totally rolled-out (DWN) state. In one embodiment of the invention, the means comprise the application of a definite voltage and/or the transfer of a definite charge to the actuator. In another embodiment, the stationary electrode unit (SE) is composed of several segments of different drive electrodes (SE1, SE2) that can selectively be activated to roll the actuator (100) to a desired position.

The invention relates to a micro-electro-mechanical system (MEMS) comprising ciliary actuators that are electrically driven. Moreover, it relates to a method for controlling such a system and to a use of such a system.

In literature, an actuator has been described comprising a flexible electrode that can completely roll-out upon application of a voltage (Dirk J. Broer, Henk van Houten, Martin Ouwerkerk, Jaap M. J. den Toonder, Paul van der Sluis, Stephen I. Klink, Rifat A. M. Hikmet, Ruud Balkenende: “Smart Materials, Chapter 4 in True Visions: Tales on the Realization of Ambient Intelligence”, ed. by Emile Aarts and José Encamaçao, Springer Verlag (2005), which is enclosed to the present application by reference). An array of such actuators may particularly be used in microfluidic systems for fluid manipulation.

Based on this situation it was an object of the present invention to provide means for a more elaborate control of a micro-electro-mechanical actuator, particularly an actuator that is suited for moving a fluid in a microfluidic system.

This object is achieved by micro-electro-mechanical system according to claim 1, a method according to claim 21, and the use according to claim 28. Preferred embodiments are disclosed in the dependent claims.

The micro-electro-mechanical system (MEMS) according to the present invention may particularly (but not exclusively) be used in a microfluidic system for moving a fluid for purposes of mixing and/or transportation. The MEMS comprises the following components:

a) An “actuator” that comprises a “flexible electrode unit” and a “stationary electrode unit” which each can comprise one or more single electrodes together with additional components (e.g. carrier materials or intermediate layers). Moreover, the flexible electrode unit is designed in such a way that it can assume a totally rolled-up state and a totally rolled-out state upon application of appropriate electrical signals to the actuator. The electrical signals may particularly comprise voltages and/or charges, wherein here and in the following expressions like “application of a voltage to the actuator” shall be a simplified notation for the “application of a voltage between the flexible electrode unit and the stationary electrode unit” and the like.

The flexible electrode unit will typically have the shape of a strip that is fixed at one end and that rolls up in its natural state, i.e. if no voltage is applied to the actuator; if a voltage above a given limit is applied to the actuator, the flexible electrode unit will roll out and extend to a stretched configuration in which it comes in closest possible contact to the stationary electrode (though remaining electrically isolated from it) by which it is electrically attracted. The actuator may particularly be a polymer micro-electro-mechanical system as it is described in literature. The actuator will sometimes be called “ciliary actuator” due to its kinship with cilia in biological systems.

b) A “control system” for selectively driving the aforementioned actuator to at least one stable “intermediate state” in which (by definition) the flexible electrode unit is in a rolling configuration between the totally rolled-up and the totally rolled-out state. The “stability” of the intermediate state shall mean in this context that this state is not only transiently passed when the actuator moves from a rolled-up to a rolled-out configuration or vice versa (which is of course the case for every such ciliary actuator), but that it can selectively be assumed for longer times than during such a transient passage; typically, the intermediate state can be assumed arbitrarily long depending on the applied control commands.

The described micro-electro-mechanical system has the advantage that it allows for a broadened spectrum of applications of the actuator because at least one intermediate rolling state can selectively be assumed additionally to the two extreme configurations (totally rolled-up or rolled-out). Thus a fine-tuning of the actuator effects becomes possible.

While the MEMS according to the present invention can in the simplest case comprise just one ciliary actuator, it will typically comprise a plurality of such actuators to allow coordinated or uncoordinated manipulations in larger areas or volumes. Preferably, the MEMS comprises an array (i.e. a one-, two-, or three-dimensional spatial arrangement) of many actuators of the kind described above, wherein said actuators may optionally be of identical design or not. Moreover, the control system will preferably be composed in this case of “local drivers” that are associated with the actuators (typically in a one-to-one relation, but possibly also in designs in which several actuators share one local driver or vice versa) and of an “external control module” that is located outside the array of actuators.

According to a further development of the aforementioned embodiment, the external control module is coupled to the local drivers in an active or passive matrix arrangement via address lines and data lines that cross at each local driver. Matrix arrangements of this kind are well known to persons skilled in the art for example from the technology of liquid crystal displays (LCDs). The address lines of such matrix arrangements typically run in parallel rows across the array, while the data lines run perpendicular thereto and parallel to each other in columns across the array. At each crossing point of an address line and a data line, a local driver circuit is connected to these lines in such a way that it can selectively be accessed by the external control module if the mentioned address line and data line are both “active”. While the signals on the address lines typically serve only for the selection of the local drivers in a certain row of the actuator array, the signal on a data line (e.g. a voltage or a current) typically represents some kind of information that has to be passed on to the associated local driver. In an active matrix (in contrast to a passive matrix), said information passed from a data line to the local driver is preserved there (until it is overwritten) even if that particular local driver is no longer addressed for an access from the external control module.

### A. Charge/Voltage Driven Control

In the following, a class of particular embodiments of the present invention will be discussed which are characterized in that the control system is adapted to drive the actuator to a stable state in which a given final voltage and/or a given final charge difference prevails between the flexible electrode unit and the stationary electrode unit (in these embodiments, the flexible and the stationary electrode unit will typically comprise just one single electrode each). As will be explained in detail with reference to the Figs., this design relies on the fact that the degree of rolling-up or rolling-out of a ciliary actuator depends uniquely on the charge difference between the flexible and the stationary electrode unit. Because the actuator can be seen as a capacitor with a variable capacitance that changes in accordance with the rolling state of the flexible electrode unit, the aforementioned charge difference corresponds to what is usually called “the charge stored on a capacitor” (strictly speaking, the charge difference is the double of the charge stored on the capacitor, because for each electron that is stored on one electrode of the capacitor one electron is removed from the counter electrode). Moreover, it is known that there is a fixed relation Q=C·V between the charge Q, the capacitance C, and the voltage V of a capacitor. In summary, the final charge stored on an actuator (seen as a capacitor) and the final voltage across this actuator in its associated stable resting state are both uniquely related to the rolling state of the actuator. Control of the final charge or the final voltage of the actuator is therefore tantamount to the control of its rolling state.

In a first particular realization of the aforementioned approach, the control system is adapted to apply repeatedly the given final voltage to the actuator for durations that are shorter than the mechanical reaction time of the actuator. While it will in principle suffice to clamp an actuator to a constant voltage source and wait until it assumes a mechanically stable state with the applied final voltage prevailing across it (i.e. between the flexible and the stationary electrode unit), this simple solution is unfavorable in actuator arrays with a more or less large number of actuators that have to be individually controlled in the shortest possible time. Applying the given final voltage repeatedly for only very short pulse durations to the actuator solves this problem, because the slow movement of the actuator to a new rolling state, that is induced by the charge transferred to the actuator during a first pulse, can happen in the time until the next voltage pulse is applied, wherein the control system can already access other actuators during this time. When the second voltage pulse is applied, the considered actuator has (at least approximately) assumed its new stable rolling state, and the associated change of its capacity allows the control system a further transfer of charge with the same voltage as during the first pulse. In this way, the repeated application of the final voltage will bring the actuator iteratively as close as desired to the desired intermediate state in which the final voltage stably prevails. It should be noted that the “mechanical reaction time” of the actuator that was mentioned above shall characterize its mechanical behavior and has to be defined appropriately for this purpose. In one possibility proposed here, the mechanical reaction time is defined as the time that the actuator needs (e.g. in vacuum) to move from its totally rolled-out to its totally rolled-up state provided that the applied voltage is a step function with the final voltage being zero.

As was already said, the aforementioned embodiment is particularly suited for arrays of actuators. In a further adaptation to the previously mentioned embodiment of an actuator array with an external control module and local drivers, the local drivers comprise a switch—preferably a thin-film transistor—that is controlled by an address line and that connects the stationary electrode unit (or, less favorably, the flexible electrode unit) of the associated actuator to a data line. Activating the address line will then select the linked local drivers and connect them to the associated data lines on which desired signals, e.g. the given final voltage of the aforementioned embodiment, are supplied.

In another particular realization of a charge/voltage controlled intermediate state, the control system is adapted to transfer a given amount of charge to the actuator. Again, the “transfer of an amount of charge to the actuator” shall be a short notation for what is actually the transfer of said amount of charge to the flexible electrode unit or to the stationary electrode unit (as was already explained above, the flexible and the stationary electrode unit form a capacitor, so that there is typically no net charge transfer to the actuator as a whole, but only a net transfer from one of its electrodes to the other). Being able to control the amount of charge that is transferred to the actuator provides a simple and direct means for controlling the mechanical state of said actuator, as this is uniquely related to the charge difference between the flexible and the stationary electrode units.

The aforementioned embodiment is again preferably applied to whole arrays of actuators. In the array design with an external control module and local drivers, the local drivers will then preferably comprise a (constant) current source for charging the actuator during a predetermined loading time with a predetermined loading current. The loading time and the loading current will in this case provide suitable and simple control parameters for determining the amount of transferred charge. The current source can of course also be used in a general design of a control system for at least one actuator.

In a preferred realization of the aforementioned embodiment, the current source is a (e.g. thin-film) transistor that is connected with its gate to a data line, with its source to an address line, and with its drain to the stationary electrode unit (or, less favorably, to the flexible electrode unit). When the voltage on the address line is chosen such that the transistor is in its saturated mode, it will operate as a current source, and the voltage on the data line can simply be a digital pulse that controls the duration (loading time) of current flow. Alternatively, the voltage on the data line can be an analogue pulse that controls the magnitude and (optionally) duration (loading time) of current flow.

While the previous embodiments provide means for transferring a given amount of charge to the actuator, the desired final rolling state of the actuator can only be achieved in this feedforward control approach if the total amount of charge on the actuator (seen as a capacitor) is known (and not only the amount of charge that is added in the last control step). This issue is addressed in a further embodiment of the invention, in which the control system is adapted to

a) first discharge the flexible electrode unit and the stationary electrode unit, and
b) then transfer an appropriate amount of charge to the actuator.

Discharging the electrode units beforehand is a simple means for establishing well defined starting conditions that enable well-defined, transparent results of the subsequent charge transfer. The “appropriate amount of charge” will typically be directly related to the given final charge difference that shall prevail in the desired final rolling state of the actuator (i.e. the “intermediate state”). It should further be noted that, after discharging the electrode units, the subsequent charge transfer can immediately start without waiting for any slow mechanical rolling reaction of the actuator.

The described discharge procedure can particularly be achieved in the design of the MEMS with an external control module and local drivers, if the local drivers comprise a switch—preferably a thin-film transistor—for selectively short circuiting the flexible electrode unit with the stationary electrode unit. Said switch may optionally be controlled by a dedicated access line connecting it to the external control module or by appropriate circuitry that couples it to neighboring data or address lines. The switch can of course also be used in a general design of a control system for at least one actuator.

Definite starting conditions that allow to reach stable rolling states of well defined charge or voltage are also provided in an embodiment in which the control system is adapted to

a) first drive the actuator to a well-defined rolling state, preferably the totally rolled-up or the totally rolled-out state, and
b1) then apply an appropriate driving voltage for an associated driving duration to the actuator; or
b2) then transfer an appropriate amount of charge to the actuator.

The well-defined rolling state that is assumed in step a) is in general associated with known electrical conditions in terms of voltage and/or charge difference across the electrode units. If the defined rolling state is for example the totally rolled-up state, then this voltage and charge difference can simply be zero. Based on such definite electrical starting conditions, an appropriate driving voltage and an associated driving duration during which is this voltage is applied (or, in case b2), an appropriate amount of charge) can readily be determined from theoretical considerations or experimental data and thereafter be applied to make the actuator transit to the desired rolling state (i.e. the “intermediate state”).

### B. Multiple Drive Electrodes

In the following, a series of embodiments of the present invention will be described that are characterized in that the flexible electrode unit and/or preferably the stationary electrode unit comprises at least two selectively addressable “drive electrodes”. In this case, there exist the alternatives to activate (i) no drive electrodes at all, (ii) the first drive electrode only, (iii) the second drive electrode only, or (iv) both drive electrodes simultaneously. This yields a total of four different activation patterns, wherein the activation of only a single drive electrode can be used to established a desired stable intermediate rolling state of the actuator.

In a preferred realization of the aforementioned approach, the drive electrodes are disposed in sequential order as seen in the rolling direction of the flexible electrode unit. Starting from a rolled-up state of the actuator, in which all drive electrodes are inactive, it is then possible to sequentially activate one drive electrode after the other (starting from the appropriate end of the electrode sequence), wherein the flexible electrode will in each activation step move so far that it just comes into closest contact to the activated electrodes.

In another preferred embodiment, the drive electrodes have a structure of interdigitated combs, i.e. combs with meshing segments (prongs). In this way the segments of the combs can be arranged in an alternating sequence (seen in the rolling direction of the flexible electrode unit), which allows in principle for a step wise control as in the previous embodiment.

In the aforementioned embodiment, the control system is preferably adapted to activate the two drive electrodes in an alternating sequence until the desired intermediate rolling state is reached. Just two drive electrode will then suffice to establish a “road” on which the flexible electrode unit can step-wise roll to the position of any desired segment of the combs.

According to a further development of the invention, the MEMS with drive electrodes comprises a selectively addressable “hold electrode” that is arranged at at least one location between said drive electrodes (wherein “between” is seen in rolling direction of the flexible electrode unit). When the flexible electrode unit has for example rolled out to a certain position by the coordinated activation of the drive electrodes as described above, it can be kept in this state by activating the hold electrode even if both drive electrodes are inactivated afterwards. This possibility is particularly useful in passive matrix arrangements in which the drive electrodes cannot continuously be kept activated.

### C. General Variants of the MEMS, Method and Usage

The following variants of the invention can be realized in combination with each of the above described embodiments.

In a first of these variants, the control system comprises a “memory module” for storing previous control actions and a “processing module” for calculating appropriate actual control actions based on the desired intermediate state of the actuator and the stored previous control actions. The memory module allows to determine the present state of an actuator, for example its charge or voltage, without the need of resetting the actuator to a definite state before the next control action is applied.

In another variant of the invention, the control system is adapted to drive the actuator with various speeds through a sequence of (totally rolled-up, totally rolled-out, and/or intermediate) states. Even if the speed of the mechanical transition between two subsequent states of the actuator cannot be influenced, it is nevertheless possible to vary the mean speed with which the actuator passes a series of (stable) rolling states by varying the time it rests in each of the states.

The invention further relates to a method for controlling a MEMS with a ciliary actuator comprising a flexible electrode unit and a stationary electrode unit, wherein the flexible electrode unit can assume a totally rolled-up state and a totally rolled-out state upon application of appropriate electrical signals (e.g. voltages or charges) to the actuator, and wherein the method comprises the selective driving of the actuator to at least one stable intermediate state in which the flexible electrode unit is in a rolling state between the totally rolled-up and the totally rolled-out a state.

The method comprises in general form the steps that can be executed with a MEMS of the kind described above. Therefore, reference is made to the preceding description for more information on the details, advantages and improvements of that method.

The invention further relates to the use of the micro-electro-mechanical systems described above for molecular diagnostics, biological sample analysis, chemical sample analysis, food analysis, and/or forensic analysis. A device according to the present invention may be of use in a broad variety of systems and/or applications, amongst them one or more of the following:
biosensors used for molecular diagnostics, e.g. biosensors making use of magnetic beads that are directly or indirectly attached to target molecules;
rapid and sensitive detection of proteins and nucleic acids in complex biological mixtures such as e.g. blood or saliva;
electrolysis to create a local pH variation for cell lysing or protein manipulation;
high throughput screening devices for chemistry, pharmaceuticals or molecular biology;
testing devices e.g. for DNA or proteins e.g. in criminology, for on-site testing (in a hospital), for diagnostics in centralized laboratories or in scientific research;

tools for DNA or protein diagnostics for cardiology, infectious disease and oncology, food, and environmental diagnostics;
tools for combinatorial chemistry;
analysis devices.

As will be appreciated by those in the art, the material in the device may comprise any number of things, including, but not limited to, bodily fluids (e.g. blood, urine, serum, lymph, saliva, anal and vaginal secretions, perspiration and semen) of virtually any organism, with mammalian samples being preferred and human samples particularly preferred; environmental samples (e.g. air, agricultural, water and soil samples); biological warfare agent samples; research samples (i.e. in the case of nucleic acids).

In the case of applications of the present invention towards devices for the detection of one or more target molecules in a fluid sample, especially to the field of devices for the detection of biomolecules in aqueous solution, the target molecule(s) may be, but not limited to, the product(s) of an amplification reaction, including both target and signal amplification); purified samples, such as purified genomic DNA, RNA, proteins, etc.; raw samples (bacteria, virus, genomic DNA, etc.); biological molecular compounds such as, but not limited to, nucleic acids and related compounds (e.g. DNAs, RNAs, oligonucleotides or analogs thereof, PCR products, genomic DNA, bacterial artificial chromosomes, plasmids and the like), proteins and related compounds (e.g. polypeptides, peptides, monoclonal or polyclonal antibodies, soluble or bound receptors, transcription factors, and the like), antigens, ligands, haptens, carbohydrates and related compounds (e.g. polysaccharides, oligosaccharides and the like), cellular fragments such as membrane fragments, cellular organelles, intact cells, bacteria, viruses, protozoa, and the like.

These and other aspects of the invention will be apparent from and elucidated with reference to the embodiment(s) described hereinafter. These embodiments will be described by way of example with the help of the accompanying drawings in which:

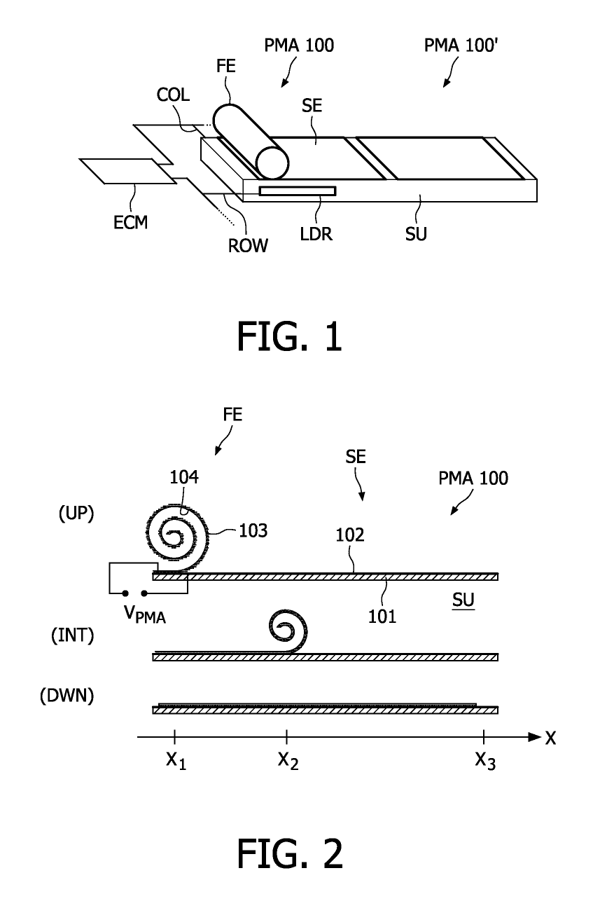

FIG. 1 shows schematically in a perspective view two neighboring polymer-MEMS actuators (PMAs) in a totally rolled-up (left) and a totally rolled-out (right) rolling state;

FIG. 2 shows schematically a side view of a PMA in the totally rolled-up state (top), an intermediate rolling state (middle), and the totally rolled-out state (bottom);

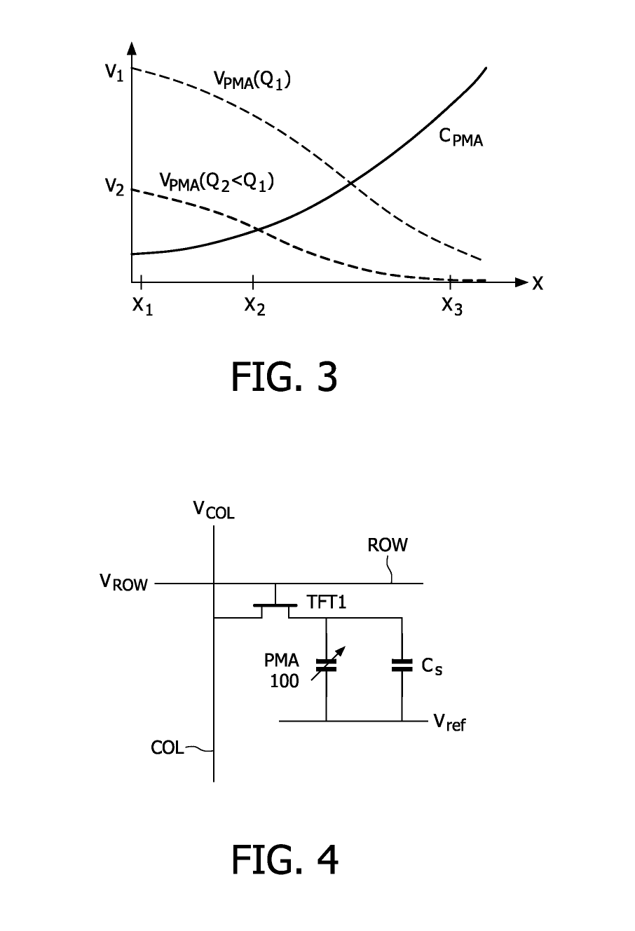

FIG. 3 illustrates in a diagram the capacitance and, for two different starting voltages, the voltage of the PMA of FIG. 2 in dependence on the different rolling states;

FIG. 4 shows a local driver in an array of PMAs by which given driving voltages can be applied to a PMA;

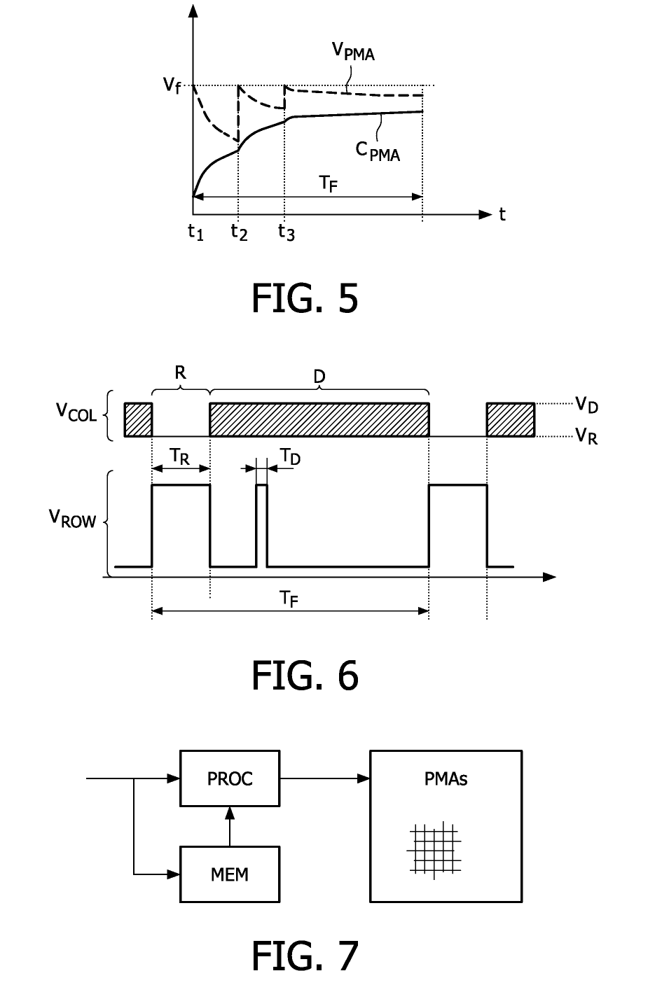

FIG. 5 shows a representative course of the capacitance and the voltage of the PMA of FIG. 4 during a typical repeated addressing process;

FIG. 6 shows typical signals on the data line and the address line for the local driver of FIG. 4 if the associated PMA is reset to a definite mechanical state previous to a control action;

FIG. 7 shows the block diagram of a MEMS using a memory for tracking the history of control actions;

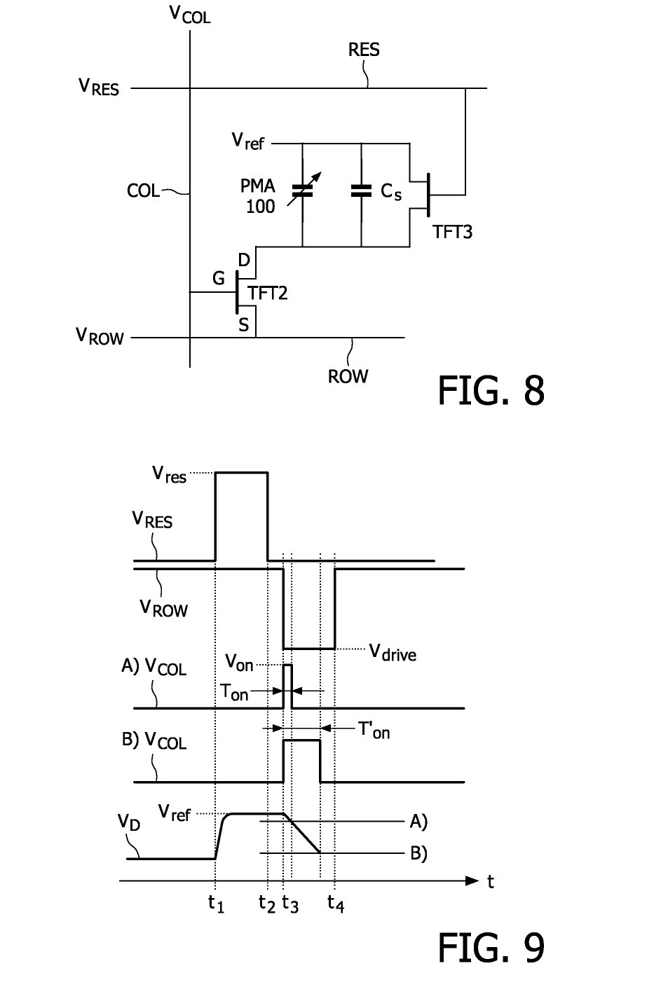

FIG. 8 shows a local driver in an array of PMAs by which constant loading currents can be applied for loading times;

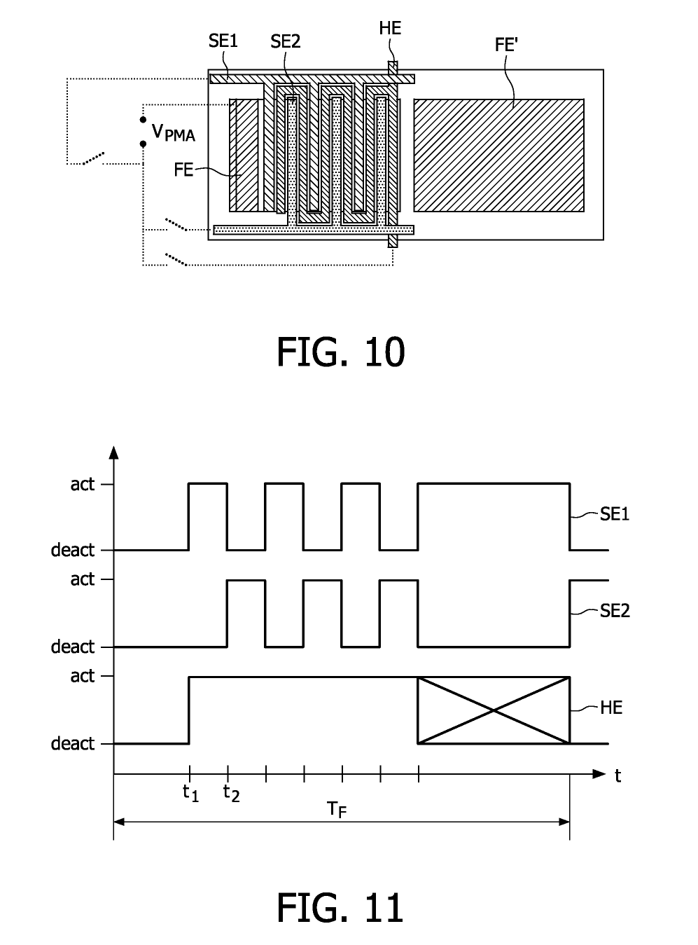

FIG. 9 shows representative waveforms for (from top to bottom) the reset voltage, the voltage on the address line, a first example of the voltage on the data line, a second example of the voltage on the data line, and the resulting PMA voltage in a typical control of the embodiment of FIG. 8;

FIG. 10 shows another embodiment of the present invention in which two drive electrodes with a meshed-comb structure and a hold electrode are used to drive the PMA into intermediate rolling states;

FIG. 11 shows representative control actions for the first drive electrode (top), the second drive electrode (middle), and the hold electrode (bottom) of the embodiment of FIG. 10.

Like reference numbers in the Figs. refer to identical or similar components.

Biochips for (bio)chemical analysis, such as molecular diagnostics, are becoming an important tool for a variety of medical, forensic and food applications. In almost all of the protocols that one wishes to carry out on a lab-on-a-chip, the transportation of fluid and in particular of bio-particles within that fluid, is crucial. Possible transportation methods for the actuation of a bio-fluid include electrical actuation, ((di)electrophoresis and electroosmosis), capillary movement, pressure driving via MEMS, and thermal gradients. The present invention is primarily concerned with polymer-MEMS actuators (abbreviated “PMAs” in the following) for fluid actuation, but could also be used in relation to other actuators. PMAs mimic a micro-fluidics manipulation mechanism “designed” by nature when beating cilia are collectively covered over the external surface of micro-organisms (e.g. paramecium and pleurobrachia). A cilium can be viewed as a small hair or flexible rod (typical length 10 μm and diameter 0.1 μm) attached to the surface. Apart from propulsion of micro-organisms, other functions of cilia are in cleansing of gills, feeding, excretion, and filtering. This effective micro-fluidics principle can be copied by polymer micro-actuators responding to an applied electrical or magnetic field by changing their shape. The typical structure is that of a curled micro-beam, which unrolls when the field is applied and returns to its original shape by elastic recovery. The actuators can be fabricated using standard micro-technology combined with polymer processing.

PMAs include for example electrostatically actuated polymer composite structures (PolyMEMs) for the manipulation of fluids. An example of these structures can be seen in FIGS. 1 and 2. FIG. 1 shows schematically a perspective view of a MEMS with two neighboring PMAs 100, 100′ forming a part of an array of possibly several thousands of such actuators, wherein the left PMA 100 is shown in the totally rolled-up and the right PMA 100′ in the totally rolled-out state. FIG. 1 indicates that the system further comprises an external control module ECM that it is connected in a matrix arrangement by data lines COL running along columns and address lines ROW running along rows ROW to local drivers LDR that are associated to each PMA. The local drivers LDR are preferably realized in the same substrate SU (e.g. glass, plastic film, metal film, silicon) that carries the PMAs 100, 100′.

The PMA 100 is shown in more detail in the schematic cross-sections of FIG. 2. It consists of an under-electrode 101 on the substrate SU that is covered by an acrylate film 102 (constituting a “stationary electrode unit SE”), and a second acrylate film 103 also covered with an electrode 104 (constituting a “flexible electrode unit FE”). The second acrylate film 103 is structured and freed from the underlying substrate for instance by photo-lithography and sacrificial layer etching. Upon applying a voltage difference V_{PMA} between the two electrodes 102 and 104, this film can overcome the force caused by internal stress and roll-out (rolling state DWN in FIG. 2). When the voltage is removed, the flexible electrode unit FE rolls-up again to its original position (rolling state UP in FIG. 2). The described structures can be between 15 and 100 μm in length and can be actuated at frequencies of 20-30 Hz, even in the presence of a fluid. It has been shown that such structures can be used to mix fluids efficiently.

For electrostatic actuation of PMAs of the kind described above it is important that the state of the polymer structure can be accurately controlled. This is crucial for example for fluid transport where the best results are achieved when different groups of structures are situated sequentially in the direction of the required flow and can be activated with a phase difference. Accurate control of the structures is also necessary for chaotic mixing of fluids where a 90° phase difference is required between adjacent structures. In addition it is also important to control the rate at which the rolling process occurs. A major problem for accurate control of the PolyMEMS structures is however that the structures tend to completely roll-up or roll-out once the voltage V_{PMA} exceeds a threshold value. As such it is not possible to perform the rolling/unrolling process in a controlled manner because it happens in all cases very rapidly.

Depending upon the exact details of the fluid actuation control, it is therefore desirable that individual PMAs can be partially rolled-up or rolled-out. Not only does this allow the array of PMAs to take on more configurations, it also allows for the structures to be rolled-up at different speeds, by effectively conducting the rolling or unrolling process in a series of steps. Whilst each of these steps may occur rapidly, the total time required for the complete rolling or unrolling may then be controlled by tuning the time between partial rolling steps as required.

FIG. 3 shows the dependence of the capacitance C_{PMA} of the capacitor that is formed by the flexible electrode unit and the stationary electrode unit of an actuator on the rolling state of said actuator (characterized by its position x as defined in FIG. 2), which is a key feature for a first group of embodiments of the invention. It can be seen from the diagram that the capacitance C_{PMA} of the PMA is largely determined by how far the PMA has rolled out, wherein the capacitance C_{PMA} rises as the PMA unrolls. Also shown (by dashed lines) is the way in which the voltage V_{PMA} on the PMA decreases as the PMA un-rolls. The upper curve shows the voltage variation assuming the initial PMA voltage V_{PMA} has a value V₁, or, equivalently, that the total (positive) charge stored on the PMA (i.e. on either the flexible electrode unit or the stationary electrode unit) has a value Q₁. The lower curve shows the effect of starting at a lower initial voltage V₂<V₁, or, equivalently, having a lower total (positive) charge Q₂<Q₁ stored on the PMA. This form of the curves is caused by a combination of the conservation of charge on the PMA and the rise in capacitance C_{PMA} due to the increasing contact area between the flexible and the stationary electrode units FE, SE. The final rolling state of the PMA will be at some position x₂ (corresponding to the intermediate rolling state INT in FIG. 2) where the capacitance is C_{PMA}=C_{f} and the voltage is V_{PMA}=V_{f} which obey the condition (with i=1; 2 and with Cₘᵢₙ being the capacitance of the PMA in its totally rolled-up state)

C_{f}·V_{f}=Qᵢ=Cₘᵢₙ·Vᵢ. (1)

This position will be stable because, if the PMA unrolls further the voltage V_{PMA} between the electrodes on the freed film and on the substrate will fall. As it is this voltage which provides the driving force to un-roll the PMA, any reduction will alter the balance between the electrical force and the mechanical forces trying to roll it up again, and the PMA will move back. Similarly, any attempt by the PMA to roll up more reduces the capacitance and increases the electrical un-rolling force making the PMA return to its original position.

FIG. 4 shows one embodiment of a local driver LDR by which the above principles can be exploited for bringing the PMA 100 to a definite intermediate rolling state INT. The local driver LDR (also called “PMA driver” in the following) belongs to an active matrix in which the external control module is adapted to drive it according to a well defined relationship between the position of the PMA and the voltage delivered to the active matrix PMA driver. The basic form of the circuit is similar to that used in active matrix LCDs with a thin film “driver transistor” TFT1 (which can be of any type, e.g. a-Si or poly-Si) whose gate is connected to an address line ROW and whose source is connected to a data line COL. The drain of the driver transistor TFT1 is connected electrically to one of the electrodes in the PMA (either that the flexible electrode or the stationary electrode), while the other PMA electrode is connected to a fixed voltage V_{ref}. In a preferred embodiment, the drain of the driver transistor TFT1 will be connected to the stationary electrode on the substrate of the PMA, whereby the flexible electrode may be implemented in the form of a common electrode. This has the advantages that the freed film electrodes need not be electrically connected to the active matrix substrate and, as all PMA freed films will be electrically connected, only a single electrical connection to this freed film will be required. This considerably improves the manufacturing yield for such PMAs. In addition, by choosing a voltage close to 0 V for the flexible electrode (which is in intimate contact with the fluid), it is possible to avoid any unwanted electrolysis in the fluid (the stationary electrode on the substrate of the PMA is covered by an insulating layer, which will prevent interaction with the fluid). The drain of the driver transistor TFT1 is also connected to a storage capacitor C_{S} which may be formed by stray capacitances in the PMA structure or deliberately fabricated as a separate component according to principles known from Active Matrix Liquid Crystal Display (AMLCD) technology and which is further connected to the reference voltage V_{ref}.

Addressing can be done in the same way as is used in AMLCD, i.e. data is applied to the data lines COL and a gate pulse is applied to the address lines ROW which switches on all the driver transistors TFT1 in one row of the PMA array. The column voltages are then loaded onto the PMA driver capacitances and the transistor TFT1 is turned off, leaving the PMA driver isolated. As is the case, voltages of different polarity may be used interchangeably, as only the magnitude of the voltage determines the rolling state of the PMA. For this reason, any of the known voltage inversion schemes from LCD driving may be implemented as preferred embodiments of the invention (such as frame, line, column or pixel inversion schemes). A key point for understanding the principle of this approach is that, once the driver transistor TFT1 has been turned off, the charge on the PMA driver capacitances is fixed at a value Q₀=C₀·Vᵢ, where C₀=C_{PMA}+C_{S} is the common capacitance of the PMA plus the capacitance C_{S} of the storage capacitor at the moment the transistor TFT1 is turned off and Vᵢ is the voltage across that capacitance once the transistor TFT1 has been turned off (this assumes that there is no current leakage between the two electrode units). The final rolling state of the PMA is therefore uniquely defined by the value of charge, Q₀, placed on the PMA driver during the addressing period, which in turn is defined by the applied voltage Vᵢ and the common capacitance C₀.

While the applied voltage Vᵢ is clearly defined by the voltage applied to a PMA driver via the data lines COL during the addressing period, the value of the common capacitance C₀ depends on the previous state of the PMA. According to the principles explained above, a PMA with a fully un-rolled freed film will yield a large value of the common capacitance C₀ while a PMA which was in a state where the freed film was fully rolled-up will yield a low value of the common capacitance C₀. The amount of variation in the common capacitance C₀ can be reduced by having a large storage capacitor C_{S} in parallel with the PMA capacitance C_{PMA}, but this reduction in the capacitance variation also reduces the effectiveness of the mechanism which allows a specific partial rolling to be defined as the slope of the common capacitance C₀ versus PMA freed film position curve is reduced.

It is therefore desirable for the control system to have information about the previous state of the PMA or to address the PMA driver more than once during the frame time T_{F}, wherein the term “frame time” refers to the time duration that is available for a completed programming cycle (“frame”) of the whole array of PMAs or of those arrays which require actuating within the given application. Knowledge of the initial state of a PMA may be obtained in different ways. Some data defining the previous state may for example be stored in a memory, wherein this information can then be used to determine actual drive signals. Alternatively, the PMAs can be reset to a known state before addressing. Arising from this understanding of the system there are several basic approaches to addressing an active matrix PMA array which are described in more detail in the following.

The approach of addressing a PMA driver more than once during the frame time T_{F} relies on the fact that if a PMA driver is addressed several times with the same data (i.e. the same voltage V_{COL}=V_{f} on the data lines COL), the capacitance change during the subsequent periods gets smaller and smaller so that the final state can be defined to within any given degree of accuracy by a known number of addressing cycles. In practice a small number of addressing cycles will typically give a good result as the changes in each successive cycle decrease rapidly.

The aforementioned effect is illustrated in FIG. 5. The PMA array is addressed at three times t₁, t₂, and t₃ in rapid succession at the beginning of the considered frame, wherein the desired PMA voltage, V_{f}, is placed on the PMA driver each time. The time durations of the (approximately instantaneous) addressing steps are very short, particularly shorter than the mechanical reaction time of the PMA. After the third addressing step, the further change in PMA capacitance C_{PMA} and PMA voltage V_{PMA} are minimal, and the PMA is in the desired state or very close to that state at the end of the frame time T_{F}. While the Fig. shows unequally spaced addressing periods, equally spaced periods may also be used.

FIG. 6 illustrates the alternative approach of resetting the PMAs to a known (mechanical) state before addressing, wherein the PMA array is addressed twice during each frame. In the first addressing step R), all PMA drivers are reset to a known state. In order to ensure that the PMA drivers are switched to a known state a sufficiently large voltage V_{COL} may be applied so that for all initial values of the common capacity C₀ the final voltage V_{f} (defined as in equation (1)) is always equal to or greater than the voltage Vₛₐₜ required to drive the PMA into the fully rolled-out state in which it has its maximum capacitance, Cₛₐₜ. This voltage must have a value of at least Vₘᵢₙ where Vₘᵢₙ·Cₘᵢₙ=Cₛₐₜ·Vₛₐₜ (with Cₘᵢₙ being the minimal possible capacitance of the PMA). Alternatively, the PMA drivers may be addressed at such a low voltage V_{COL}=V_{R} that they will return to the fully rolled-up state (this will require that the rolling occurs well within a frame time T_{F}, so will work best for small PMAs). A suitable addressing voltage will for example be V_{R}=0 V (i.e. no charge remains on the PMA). According to the situation shown in the Fig., the PMA drivers are addressed and the driver transistors TFT1 held in the “on” state for a period T_{R} sufficiently long for the PMAs to reach a reference state of known capacitance, which would most probably be either the fully extended or fully rolled state. The driver transistors TFT1 can then be turned off and be addressed in the next step D) the normal manner with a data signal V_{COL}=V_{D} on the data lines.

Whilst the described re-setting is an extremely effective method for realizing an accurate degree of rolling of a PMA, this inevitably results in a motion of the PMA. In order that such a motion has no detrimental effect on the motion of the fluid or particles in the fluid, the following measures can be taken:
Resetting is carried out in a period of time well before or well after the fluid manipulation is being carried out (i.e. all PMAs are in a “ready” state and only a single rolling event is considered).
The resetting is carried out very slowly, whilst actuation is fast (e.g. to create turbulence).
Adjacent PMAs are reset to the opposite reset states (e.g. even rows/columns reset to fully rolled-up state, odd rows/columns reset to fully rolled-out state, checkerboard pattern with adjacent PMAs reset to opposite states). In this manner, no net fluid motion will be realized during the resetting process.

The alternative approach of storing data defining the previous state of the PMA array is illustrated in FIG. 7. Here, a memory MEM is used to store the data of the PMA positions of the previous frame number N−1. These signal levels define the capacitance of the PMAs and so the required driving voltage V_{D}(N) in the next frame N can be calculated from the desired final voltage, V_{f}(N), the predicted final PMA capacitance, C_{PMA}(N), and the current capacitance, C_{PMA}(N−1) produced by the driving signal in the previous frame which can be derived from the previous PMA driving voltage, V_{D}(N−1). The driving voltage is then calculated in a processing module PROC from the relationship:

V_{D}(N)=C_{PMA}(N)·V_{f}(N)/C_{PMA}(N−1).

Such a memory based system could also be exploited to improve e.g. the response speed of a large or otherwise slow responding PMA, by intentionally overdriving in a first frame or several frames the PMA driver with a higher voltage than required to arrive at the desired rolling state (subsequent frames to be e.g. driven at equilibrium voltage).

FIG. 8 shows an alternative embodiment of a local driver LDR that is used in an active matrix approach for controlling a PMA 100. The gate G of a thin film driver transistor TFT2 (e.g. a-Si or poly-Si) is connected in this case to a data line COL, its source S to an address line ROW, and its drain D to the PMA and again a storage capacitor C_{S}. The capacitance of the storage capacitor C_{S} can for example be formed via tuning the area of permanent attachment between the stationary electrode and the flexible electrode (i.e. the region between the left ends of electrodes 101, 104 and position x₁ in FIG. 2). Alternatively the capacitance C_{S} may be formed by other stray capacitances in the PMA structure or deliberately fabricated as a separate component as is known from AMLCD technology. The storage capacitor C_{S} is further connected to a reference voltage V_{ref}.

The drain D of the driver transistor TFT2 is connected electrically to one of the electrodes in the PMA (either the flexible electrode 104 on the freed film or the stationary electrode 102 on the substrate) and the other PMA electrode is connected to the fixed reference voltage V_{ref}. In a preferred embodiment, the drain of the driver transistor TFT2 will be connected to the stationary electrode on the substrate, whereby the freed film electrode may be implemented in the form of a common electrode.

As was explained above with reference to FIGS. 2 and 3, the final state of a PMA is uniquely defined by the value of charge, Qᵢ, placed on the PMA. The PMA driver circuit shown in FIG. 8 is designed to allow a known value of charge, ΔQ, to be placed on the PMA driver capacitances when an appropriate drive scheme is used. According to one such drive scheme, the driver transistor TFT2 is set in a saturated mode during addressing so that it operates as a current source and loads the charge ΔQ onto the common PMA driver capacitance C₀. This charge ΔQ depends only on the loading current Iₒₙ, through the driver transistor TFT2 and the loading time Tₒₙ for which the driver transistor TFT2 is switched on according to the formula

ΔQ=Iₒₙ·Tₒₙ. (2)

Provided the voltage V_{PMA} on the PMA is such that driver transistor TFT2 remains in its saturated mode, the loaded charge ΔQ does not depend on the PMA driver capacitance C_{PMA} and so the previous rolling state of the PMA does not affect the state into which it is switched during the addressing period. Control of the degree of rolling can be achieved by varying the loading time Tₒₙ. This has an additional advantage in that the signal on the data lines COL can be a purely digital signal so the cost of the column drivers in a PMA array using this type of addressing will be low. In order to achieve a known value of the final charge Q on the PMA it is necessary to start the charging from a known state, e.g. where the PMA voltage V_{PMA} and hence charge are zero. This can be achieved in several ways, for example as shown in the Fig. by having an extra thin-film transistor TFT3, which can be turned on by using a reset pulse Vᵣₑₛ on a reset line RES to short the flexible and the stationary electrode and thus to discharge the PMA and the storage capacity C_{S} before the data loading occurs.

It should be noted that the aforementioned discharging does not necessarily result in a motion of the freed film, as typically the discharging will take place in a time period which is much shorter (<<1 ms) than the mechanical response time of the PMA (>>1 ms). For this reason, the discharging-reset is different from a rolling-state-reset of the PMA as it was described above (FIG. 6).

An alternative method for achieving a known value of the final charge on the PMA is to use, in a design like that of FIG. 7, a memory to store the data of the PMA positions of the previous frame. The previous position gives then the initial state of the charge on the PMA, from which it is possible to determine the change ΔQ in charge required to arrive at the desired new value. In this case the PMA driver should comprise means for both charging and discharging the PMA.

The operation of the PMA driver of FIG. 8 is illustrated by the timing diagram of FIG. 9. The addressing process starts at a time t₁ by taking the gate of the reset transistor TFT3 to a high voltage Vᵣₑₛ, turning this transistor on and discharging any voltage present across the PMA capacitance and storage capacitor C_{S}. The drain voltage V_{D} rises accordingly to the reference voltage V_{ref}. At a time t₂, the reset transistor TFT3 is turned off and a short time later, at time t₃, the voltage V_{ROW} on the addressing lines—and thus the source of the driver transistor TFT2—is brought negative to a voltage V_{drive}. At the same time a gate pulse V_{COL}=Vₒₙ is applied on the data lines COL, turning the driver transistor TFT2 on. Because the TFT2 drain voltage V_{D}=V_{ref} is more positive than (V_{drive}−V_{T}) (with V_{T} being the threshold voltage of the driver transistor TFT2), the driver transistor TFT2 is biased into its saturated mode and delivers a constant current provided that V_{D} remains above (V_{drive}−V_{T}). The drain voltage V_{D} falls until a time (t₃+Tₒₙ) when the TFT2 gate is taken well below the voltage (V_{dive}−V_{T}), turning the driver transistor TFT2 off. The Fig. illustrates this situation for two cases A) and B) with different values Tₒₙ, T′ₒₙ , of the loading time, corresponding to two different degrees of rolling. At a time t₄ the TFT2 source is taken high so that subsequent addressing pulses on the column which are intended for other PMAs do not turn the driver transistor TFT2 on again so the PMA remains isolated and the loaded charge remains constant.

The reset signal for the reset transistor TFT3 may be applied as shown in FIG. 8 by an additional, separate row address line RES for each row of PMAs. In this case a preferred approach would be to be resetting the PMAs in a row n during the period when data is being loaded onto the PMAs in the previous row (n−1). If low temperature poly silicon (LTPS) is used then, by using a p channel thin-film transistor for TFT3, its gate can be connected to the previous row so the pulse which turns on the driver transistor TFT2 in a row n will turn on the reset transistors TFT3 in the following row (n+1) at the same time, avoiding the need for two row addressing lines per PMA array row.

It should be noted that an alternative drive method is to vary the gate voltage on the driver transistor TFT2 to achieve the required charge by controlling the current Iₒₙ through this transistor and keeping the time Tₒₙ, for which the transistor is switched on, constant (according to formula (2), varying either Iₒₙ or Tₒₙ allows ΔQ to be controlled). This requires an analogue column driver, but would allow standard driver ICs developed for AMLCDs and AMOLEDs (active matrix organic LED displays) to be used and also may give better control of low degrees of rolling in large PMA arrays where the need to achieve very short values of Tₒₙ may be an issue as the short pulses may become severely degraded by the RC time constant of the columns. It is also possible to use a combination of a control of Iₒₙ and Tₒₙ to control the value of the charge ΔQ loaded onto the PMA.

The uniformity of the degree of rolling is in the previous approaches directly related to variations in the current sources, particularly the trans-conductance of the driver transistor TFT2. Any variations in mobility and threshold voltage V_{T} will lead to direct changes in charging current and hence degree of rolling. This is particularly relevant for poly-Si based TFTs, and is a similar issue to that faced by AMPLED/AMOLED displays. However, because the gate voltage used in the approach where a constant driving voltage (which can be well above the TFT threshold voltage) is applied for a variable period the effect of threshold voltage variations is less critical. Moreover, embodiments of PMA driver circuits can be made in which the simple current source (driver transistor TFT2) is replaced with a known current source circuit that enhances the PMA to PMA uniformity of the charging current. Examples of such circuits are threshold voltage compensating circuits and current mirror circuits.

FIG. 10 shows in a top view two neighboring PMAs according to another variant of the invention, wherein the flexible electrode FE, FE′ is in the totally rolled-up state in the left PMA and the totally rolled-out state in the right PMA. Moreover, surface layers have partially been removed in the left part of the picture to reveal the particular electrode structure of the stationary electrode unit. This stationary electrode unit consists of two “drive electrodes” SE1 and SE2 that are selectively addressable and that are formed as combs with segments that mesh with each other from opposite sides. Moreover, a meandering “hold electrode” HE fills the intermediate space between the two drive electrodes. As will be described in the following, this particular arrangement of drive electrodes SE1, SE2 and hold electrode HE can be used to provide for partial rolling of the flexible electrode FE.

An activation pattern of the drive electrodes SE1, SE2 and the hold electrode HE that can be used to roll the PMA out (or up) is illustrated in FIG. 11. At the beginning of the frame time T_{F}, the flexible electrode FE is in its rolled-up position. The hold electrode HE and the drive electrodes SE1 and SE2 are deactivated, wherein “deactivating” means that the voltage difference V_{PMA} over the PMA is small, so that the PMA will roll-up. “Activating” means accordingly that the voltage difference V_{PMA} is sufficient to roll out the PMA.

In order to roll the PMA out the hold electrode HE is activated at a time t₁. Then the first drive electrode SE1 is activated and the flexible electrode FE rolls out across the first segment of the first drive electrode SE1 and the hold electrode HE until it comes to the second drive electrode SE2 (that is deactivated). At this point it rolls out no further and a partially rolled-up PMA device is realized, which will remain in the partially rolled state until further signals are applied to the electrodes.

When the PMA must be rolled-out further, the first drive electrode SE1 is deactivated at a time t₂ and the second drive electrode SE2 and the hold electrode HE are activated. The flexible electrode FE will then roll out across the first segment of the second drive electrode SE2 and the hold electrode HE until it comes to the next segment of the first drive electrode SE1 (that is deactivated).

This process can be repeated until the PMA reaches its desired level of unrolling or may proceed continuously with a chosen time delay to achieve a slow complete rolling-up or rolling-out of the PMA.

The described PMA device may be a part of a passive matrix array, in which case the drive electrodes SE1 and SE2 are conveniently implemented in the form of row electrodes, whilst the hold electrode HE is conveniently implemented in the form a column electrode. In this case, the drive electrodes SE1 and SE2 remain activated after addressing a row of PMAs and the PMA remains at its position due to the electrostatic force of the row electrodes. The state of the column is not important anymore as long as the row electrodes remain activated. The roll will move a little due to the column signal on the column electrode, but not much.

The rolling process can also be done by first unrolling the PMA entirely by activating both row and column electrodes and then step by step rolling a PMA up. This is done by deactivating the hold electrode when a PMA must be rolled further and then alternating the drive electrodes SE1 and SE2 as done previously.

When a PMA must not be rolled further the hold electrode HE is activated constantly. When the right level of unrolling has been reached and the frame time is passed, both drive electrodes SE1 and SE2 are activated. The process can be speeded up by first looking if a PMA is more rolled than unrolled in case one rolls a PMA completely and then start unrolling it. When a PMA is more unrolled than rolled, the PMA can first be unrolled completely and then be rolled up in steps.

The partially rollable PMA array can also be realized within an active matrix technology. In active matrix technology, it is possible to hold a voltage on an electrode at all times, even when other PMAs are being addressed by the electronics. In this case, there is therefore no requirement for a hold electrode HE. It suffices that the PMA device comprises two drive electrodes SE1 and SE2, and the flexible counter electrode on the foil. The rolling/unrolling is then realized by sequentially actuating the drive electrodes SE1 and SE2 in each PMA device. Every time the actuating voltage changes from one electrode to another, the PMA will unroll by the distance between the adjacent portions of electrodes SE1 and SE2. In this manner, controlled partial rolling at a desired rolling rate may be realized in a PMA with three electrodes. It should be noted that the direction of rolling (up or out) can in this case be influenced by the precise timing of the activations of the drive electrodes SE1, SE2. A small overlap in the activation will induce a rolling-out movement due to the attraction of the flexible electrode by both drive electrodes; no overlap or a small gap in the activation, on the contrary, will induce a rolling-up movement as the intermediate ceasing of any electrical attraction allows the mechanical forces to start a rolling-up of the flexible electrode.

The actuator could also be used for a valve with controlled, partial closing in a microfluidic system. Moreover, the actuator could be used as a light shutter in a visual device such as a display or a re-configurable lighting system, signage application etc.

Finally it is pointed out that in the present application the term “comprising” does not exclude other elements or steps, that “a” or “an” does not exclude a plurality, and that a single processor or other unit may fulfill the functions of several means. The invention resides in each and every novel characteristic feature and each and every combination of characteristic features. Moreover, reference signs in the claims shall not be construed as limiting their scope.

1. A micro-electro-mechanical system with
a) an actuator (100) comprising a flexible electrode unit (FE) and a stationary electrode unit (SE), wherein the flexible electrode unit (FE) can assume a totally rolled-up state (UP) and a totally rolled-out (DWN) state upon application of appropriate electrical signals to the actuator;
b) a control system (ECM, LDR) for selectively driving the actuator to at least one stable intermediate state (INT) in which the flexible electrode unit (FE) is in a rolling state between the totally rolled-up and the totally rolled-out state.

2. The micro-electro-mechanical system according to claim 1,
characterized in that the actuator (100) is a polymer micro-electro-mechanical system.

3. The micro-electro-mechanical system according to claim 1,
characterized in that it comprises an array with a plurality of actuators (100), wherein the control system is composed of local drivers (LDR) associated with the actuators (100) and an external control module (ECM).

4. The micro-electro-mechanical system according to claim 3,
characterized in that the external control module (ECM) is coupled to the local drivers (LDR) in an active or passive matrix arrangement with address lines (ROW) and data lines (COL) crossing at the local drivers.

5. The micro-electro-mechanical system according to claim 1,
characterized in that the control system (ECM, LDR) is adapted to drive the actuator (100) to a state in which a given final voltage (V_{f}) and/or a given final charge difference prevail stably between the flexible and the stationary electrode unit (FE, SE).

6. The micro-electro-mechanical system according to claim 5,
characterized in that the control system (ECM, LDR) is adapted to repeatedly apply the given final voltage (V_{f}) to the actuator (100) for time durations that are shorter than the mechanical reaction time of the actuator.

7. The micro-electro-mechanical system according to claim 3,
characterized in that at least one of the local drivers (LDR) comprises a switch, preferably a thin-film transistor (TFT1), that is controlled by an address line (ROW) and that connects one of the electrode units (SE) of the associated actuator (100) to a data line (COL).

8. (canceled)

9. The micro-electro-mechanical system according to claim 1,
characterized in that the control system (LDR) comprises a current source (TFT2) for charging the actuator (100) during a predetermined time (Tₒₙ) with a predetermined current (Iₒₙ).

10. The micro-electro-mechanical system according to claim 9,
characterized in that the current source is a thin-film transistor (TFT2) that is connected with its gate (G) to a data line (COL), with its source (S) to an address line (ROW), and with its drain (D) to the flexible electrode unit (FE) or to the stationary electrode unit (SE).

11. The micro-electro-mechanical system according to claim 5,
characterized in that the control system (ECM, LDR) is adapted to
a) first discharge the flexible electrode unit (FE) and the stationary electrode unit (SE);
b) then transfer an appropriate amount of charge to the actuator (100).

12. (canceled)

13. (canceled)

14. (canceled)

15. (canceled)

16. (canceled)

17. (canceled)

18. (canceled)

19. The micro-electro-mechanical system according to claim 1,
characterized in that the control system (ECM, LDR) comprises a memory module (MEM) for storing previous control actions, and a processing module (PROC) for calculating appropriate actual control actions based on the desired intermediate state (INT) of the actuator (100) and on previous control actions.

20. The micro-electro-mechanical system according to claim 1,
characterized in that the control system (ECM, LDR) is adapted to drive the actuator (100) with various speeds through a sequence of states.

21. A method for controlling a micro-electro-mechanical system with an actuator (100) comprising a flexible electrode unit (FE) and a stationary electrode unit (SE), wherein the flexible electrode unit (FE) can assume a totally rolled-up state (UP) and a totally rolled-out (DWN) state upon application of appropriate electrical signals to the actuator,
the method comprising the selective driving of the actuator (100) to at least one stable intermediate state (INT) in which the flexible electrode unit (FE) is in an intermediate rolling state (IN) between the totally rolled-up and the totally rolled-out state.

22. The method according to claim 21,
characterized in that a given final voltage (V_{f}) and/or a given final charge difference is imposed between the flexible electrode unit (FE) and the stationary electrode unit (SE) in the intermediate state (INT).

23. The method according to claim 22,
characterized in that the given final voltage (V_{f}) is repeatedly applied to the actuator (100) for pulse durations shorter than the mechanical reaction time of the actuator.

24. The method according to claim 21,
characterized in that
a) the actuator (100) is first reset to a definite state, preferably the totally rolled-up (UP) or the totally rolled-out (DWN) state,
and then
b1) an appropriate driving voltage (V_{D}) and an associated duration (T_{D}) are calculated and applied to the actuator,
or
b2) an appropriate amount of charge is transferred to the actuator (100).

25. The method according to claim 21,
characterized in that the flexible electrode unit (FE) and the stationary electrode unit (SE) are discharged beforehand.

26. The method according to claim 21,
characterized in that previous control actions are stored and taken into account when appropriate actual control actions are determined.

27. The method according to claim 21,
characterized in that the actuator (100) is driven with various speeds through a sequence of states.

28. Use of the micro-electro-mechanical system (100) according to claim 1 for molecular diagnostics, biological sample analysis, or chemical sample analysis, food analysis, and/or forensic analysis.
